(19) United States
(12) Patent Application Publication
(10) Pub. No.: US 2010/0045387 A1
(43) Pub. Date: Feb. 25, 2010

(54) OPTICAL RECEIVER-AMPLIFIER

(75) Inventor: Atsunobu Ohta, Musashino-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: YOKOGAWA ELECTRIC CORPORATION, Tokyo (JP)

(21) Appl. No.: 12/537,052

(22) Filed: Aug. 6, 2009

(30) Foreign Application Priority Data
Aug. 20, 2008 (JP) 2008-211765

(51) Int. Cl. H03F 3/08

(52) U.S. Cl. 330/308

(57) ABSTRACT

There is provided an optical receiver-amplifier wherein the need for a large capacitance capacitor for AC coupling is eliminated to thereby enable miniaturization of a receiver in whole, and output waveforms of a differential limiter amp can be rendered symmetrical with high precision while a transimpedance amp and a limiter amp can be integrated on one chip. The optical receiver-amplifier comprises a photodiode, a transimpedance amp for amplifying an output signal of the photodiode, and a DC current compensating circuit connected in parallel with the transimpedance amp for compensating for a DC-current component of an output current of the differential amp.

### FIELD OF THE INVENTION

The present invention relates to an optical receiver-amplifier, and more specifically, to improvement in characteristics of the optical receiver-amplifier, and miniaturization thereof.

### BACKGROUND OF THE INVENTION

FIG. 6 is a block diagram showing an example of a conventional optical receiver-amplifier using a transimpedance amp. The optical receiver-amplifier comprises one unit of a photodiode 1 for receiving an optical signal, a transimpedance amp 2 for linearly amplifying an electric signal converted from the optical signal received by the photodiode 1, a capacitor 3 for effecting AC coupling of an output signal of the transimpedance amp 2 to the following stage, and a differential limiter amp 5 for receiving a predetermined dc bias voltage from two unit of bias generation circuits 4a, 4b so as to adequately operate, and for amplifying a small signal output delivered via the capacitor 3 after amplified by the transimpedance amp 2 until limited to a given output amplitude.

FIG. 7 is a schematic representation showing an output signal waveform of the photodiode 1 by way of example, and the waveform represents an electric signal converted from the optical input signal, the waveform including an AC current component Iin (pp), and a DC current component Iin_dc.

FIGS. 8(A), 8(B) and 8(C) are views each showing an example of an output waveform of the transimpedance amp 2 shown in FIG. 6. It can be confirmed from the figure that a rise in optical input level, that is, an increase in current value will cause an asymmetrical rise in level of an output waveform signal without centering around a reference voltage.

FIG. 9 is a view showing an example of a simulation output waveform of the limiter amp 5 shown in FIG. 6. It can be confirmed that respective waveforms of output voltages Vout (V), VoutB (V) of the limiter amp 5, against an input voltage, are found asymmetrical.

Patent Document 1 relates to a configuration intended to attempt reduction in a circuit-mounting area, and simplification of circuit-mounting when offset compensation and phase compensation, in an optical receiver-amplifier, are carried out.

### [Patent Document 1] JP5 (1993)-218772 A

### SUMMARY OF THE INVENTION

However, with the conventional optical receiver-amplifier shown FIG. 6, if there occurs a change in the optical input level upon the output signal of the transimpedance amp 2 being inputted to the differential limiter amp 5, this will cause a large change in a voltage level of the output signal of the transimpedance amp 2 as described in the foregoing, so that after removing the DC current component contained in the output signal of the transimpedance amp 2 by effecting the AC coupling of the output signal of the transimpedance amp 2 to the following stage with the use of the capacitor 3 having a large capacitance, the output signal must be inputted to a differential input circuit such as a limiter circuit, and so forth. Hence, there is a problem in that it is not possible to achieve miniaturization of the optical receiver-amplifier.

Further, even if the AC coupling of the output signal of the transimpedance amp 2 to the following stage is effected with the use of the capacitor 3, and the DC current component contained in the output signal of the transimpedance amp 2 is removed, there still exists a problem in that asymmetry occurs to the output waveforms of the limiter amp 5 unless the bias generation circuits 4a, 4b are optimized or adjusted with high precision.

The present invention has been developed to solve those problems described as above, and it is therefore an object of the invention to provide an optical receiver-amplifier wherein the need for a large capacitance capacitor for AC coupling is eliminated to thereby enable miniaturization of a receiver in whole, and output waveforms of a differential limiter amp can be rendered symmetrical with high precision while a transimpedance amp and a limiter amp can be integrated on one chip.

To that end, in accordance with one aspect of the invention, there is provided an optical receiver-amplifier comprising a photodiode, a transimpedance amp for amplifying an output signal of the photodiode, and a DC current compensating circuit connected in parallel with the transimpedance amp for compensating for a DC-current component of an output current of the differential amp.

The DC current compensating circuit preferably comprises a differential amp, an output signal of the transimpedance amp being inputted to one of input terminals of the differential amp, a bias generation circuit for inputting a set voltage to the other input terminal of the differential amp, a capacitor coupled between an output terminal of the differential amp and an earth ground, and a current source for receiving an output signal of the differential amp and compensating for a DC current flowing through the photodiode.

The optical receiver-amplifier preferably further comprises a differential limiter amp section connected to an output terminal of the transimpedance amp, comprising an output cross-point compensating circuit for adjusting a duty ratio of the output signal of the transimpedance amp by adjusting a potential difference.

The optical receiver-amplifier is preferably made up as an integrated circuit over one chip.

The integrated circuit is preferably composed of current control type bipolar transistors.

With the present invention, adoption of such a configuration as described has made it possible to eliminate the need for a large capacitance capacitor for AC coupling to thereby enable miniaturization and integration of a transimpedance amp and a limiter amp over one chip. Hence, it is possible to provide an optical receiver-amplifier capable of operation at high speed, and having excellent characteristics.

### BRIEF DESCRIPTION OF THE DRAWINGS

FIG. 1 is a block diagram showing one embodiment of an optical receiver-amplifier according to the invention;

FIG. 2 is a view showing static characteristics of a current source 64 according to the invention by way of example;

FIGS. 3(A), 3(B) and 3(C) are views showing results of a simulation of an output of a transimpedance amp 2 according to the invention by way of example;

FIG. 4 is view showing results of a simulation of current compensation due to feedback control against optical input power received by a photodiode 1 according to the invention by way of example.;

FIG. 5 is a view showing simulation output waveforms by use of feedback control against an output cross point according to the invention by way of example:

FIG. 6 is a block diagram showing an example of a conventional optical receiver-amplifier employing a transimpedance amp;

FIG. 7 is a schematic representation showing an output signal waveform of a photodiode 1 in FIG. 6 by way of example;

FIGS. 8(A), 8(B) and 8(C) are views showing an output waveform of the transimpedance amp shown in FIG. 6 by way of example; and

FIG. 9 is a view showing a simulation output waveform of a conventional limiter amp by way of example.

### DETAILED DESCRIPTION OF THE PREFERRED EMBODIMENTS

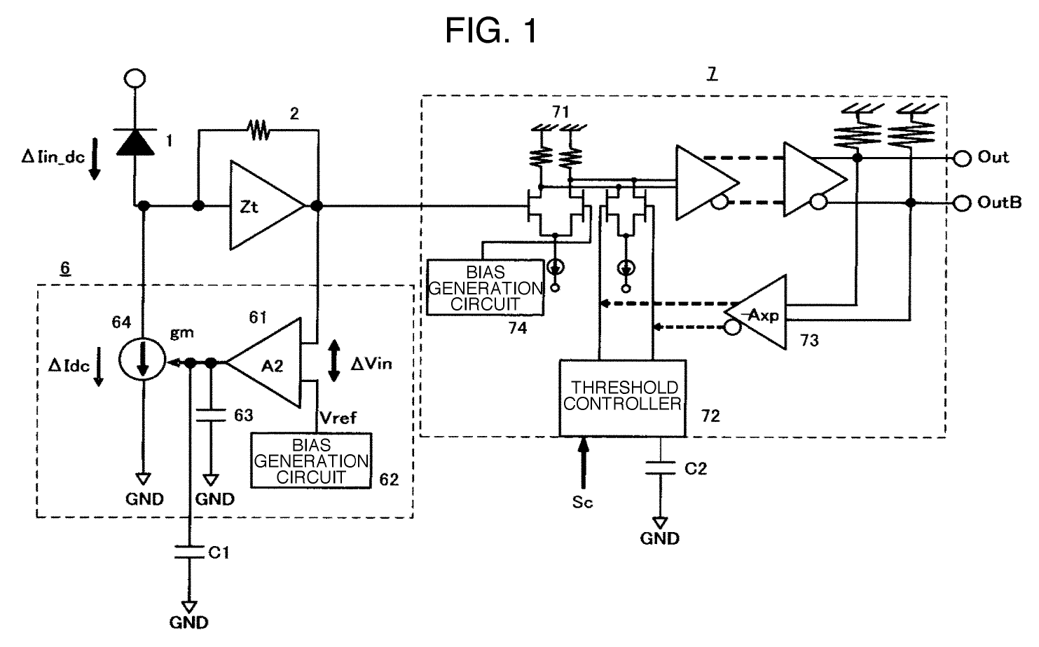

An optical receiver-amplifier according to the invention is described hereinafter with reference to the accompanying drawings. FIG. 1 is a block diagram showing one embodiment of the optical receiver-amplifier according to the invention. The optical receiver comprises a photodiode 1 which is a light-sensitive element, a transimpedance amp 2, a DC current compensating circuit 6 connected in parallel with the transimpedance amp 2, for compensating for a DC current component of an output current of the transimpedance amp 2, and a differential limiter amp section 7 connected to an output terminal of the transimpedance amp 2.

### Embodiment 1

The DC current compensating circuit 6 comprises a differential amp 61, a bias generation circuit 62 for supplying a predetermined bias voltage to the differential amp 61, a capacitor 63 coupled between an output terminal of the differential amp 61 and an earth ground, acting as an integrator for causing an AC current component of an output signal of the differential amp 61 to flow to the earth ground, thereby extracting a mean voltage value, and a current source 64 for receiving a DC voltage component of an output of the differential amp 61 as an input thereto.

The differential limiter amp section 7 comprises a limiter amp 71, a threshold controller 72 for controlling a limit operation range of the limiter amp 71, an output cross-point compensating circuit 73 for controlling a duty ratio of an output signal by adjusting a potential difference, and a bias generation circuit 74 for supplying a predetermined bias voltage to one of differential pair inputs of the limiter amp 71. Further, a control signal Sc is inputted to the threshold controller 72, and an external capacitor C2 is connected to the threshold controller 72.

Now, the operation in FIG. 1 is described hereinafter. A power supply voltage is applied to a cathode of the photodiode 1, and an anode thereof is connected to an input terminal of the transimpedance amp 2. The DC current compensating circuit 6 for subjecting an output current from the transimpedance amp 2 to feedback control is connected between the input terminal of the transimpedance amp 2, and an output terminal thereof. A DC current resulting from the feedback control by the DC current compensating circuit 6 is delivered to the photodiode 1.

The photodiode 1 functions as a current source for outputting both AC current and DC current. The DC current is delivered to the DC current compensating circuit 6, and the AC current is delivered to the transimpedance amp 2. As a result of delivery of the AC current to the transimpedance amp 2, it is possible to gain a given output voltage level from the transimpedance amp 2 regardless of magnitude of light received by the photodiode 1. Then, an output signal of the transimpedance amp 2 can be delivered to the differential limiter amp section 7.

The photodiode 1 converts a received optical input data Din into an electrical signal (current) to be then delivered to the input terminal of the transimpedance amp 2. The transimpedance amp 2 linearly amplifies the electrical signal as outputted after conversion to be delivered to one of input terminals of the differential amp 61 of the DC current compensating circuit 6. The bias generation circuit 62 supplies a bias voltage at a predetermined value to the other of the input terminals of the differential amp 61, whereupon an AC voltage and a DC voltage each are outputted from the output terminal of the differential amp 61.

The capacitor 63 is coupled between the output terminal of the differential amp 61 and the earth ground, and extracts the mean voltage value by causing the AC current component of the output signal of the differential amp 61 to flow to the earth ground, thereby stabilizing the output of the differential amp 61. The DC voltage of the output signal from the differential amp 61 is delivered to a current source (FET) 64 of a voltage control type. Further, the current source 64 supplies only the DC current flowing through the photodiode 1, and compensates for the DC current of the photodiode only. Since the photodiode 1 serves as a current source as well, for converting the input optical signal into the electric signal to be outputted, when the power supply voltage is applied thereto, and an optical signal is inputted thereto, the photodiode 1 starts outputting AC current, and DC current. Only AC current out of the output of the photodiode 1 is delivered to the transimpedance amp 2 to be linearly amplified before inputted to the differential limiter amp section 7. In the differential limiter amp section 7, a duty ratio of each of output voltages Vout (V), VoutB (V) from the limiter amp 71 is controlled to 50% by the threshold controller 72 and the feedback amp 73. Further, the limiter amp 71 undergoes limit-operation such that an output amplitude of each of the output voltages Vout (V), VoutB (V) from the limiter amp 71 will coincide with a given amplitude.

Further, an external capacitor C1 is connected to the DC current compensating circuit 6 from outside an integrated circuit. The reason for this is because a capacitor functioning as a integrator, having a capacitance value as large as about 0.1 μF, is required in the case where an attempt is made to extract only a DC current component (the mean voltage value) out of a signal such as an optical signal having a wideband frequency component, for example, in a range of on the order of 10 kHz to 40 GHz, and it is impossible to form such a capacitor on the top of an integrated circuit.

Herein, an optimum value of an amplification factor of the differential amp 61 in the DC current compensating circuit 6 is found as follows.

Assuming that the DC current flowing through the photodiode 1 is Δlin_dc, the output voltage from the transimpedance amp 2 is Vout (V), transimpedance of the amp is Zt, and an output reference voltage of the transimpedance amp 2 is V0, the following expression holds:

Vout(V)=Δlin_{—}dc×Zt+V0

Then, assuming that the amplification factor of the differential amp 61 in the DC current compensating circuit 6 is A2, a potential difference between differential inputs of the differential amp 61 is ΔVin, an output voltage from the differential amp 61 is ΔVc, and input voltages of the differential amp 61 are the output voltage Vout (V) from the transimpedance amp 2, and an output voltage from the bias generation circuit, the following equation holds:

$$\begin{matrix}Δ Vc = A 2 \times Δ Vin \\ = A 2 \times \vert Vout ( V ) - Vref ( V ) \vert\end{matrix}$$

wherein if Vref(V)=V0 is set in the bias generation circuit,

ΔVc=A2×Δlin_{—}dc×Zt (1)

Further, assuming that a DC current flowing through the current source 64 is ΔIdc, the following equation holds:

ΔIdc=ΔVc×gm (2)

wherein gm denotes transconductance.

If equation (2) is replaced with equation (1), equation (2) becomes as follows:

ΔIdc=A2×Δlin_{—}dc×Zt×gm (3)

And further, ΔIdc=Δlin_dc.

Furthermore, if parameters in equation (3) are replaced such that 500Ω is substituted for Zt, and 1 mS is substituted for gm,

A2=2 (4)

It can be confirmed from equation (4) that the optimum value of the amplification factor of the differential amp 61 is found at 2, more specifically, a gain in DC is doubled.

Thus, the transimpedance amp 2 of the present invention is provided with the DC current compensating circuit 6 in order to generate a signal of the DC current subjected to the feedback control, besides an input signal from the photodiode 1. By doing so, it is possible to amplify the output signal of the transimpedance amp 2 while keeping a voltage level of the output signal at a given level.

As a result, in contrast to the conventional optical receiver-amplifier wherein the capacitor 3 for effecting AC coupling to thereby remove the DC current component is connected to the output terminal of the transimpedance amp 2, with the optical receiver-amplifier of the invention, the capacitor 3 is no longer required, so that miniaturization, integration, and faster operation can be attained.

More specifically, since the conventional capacitor 3 for AC coupling had capacitance as large as on the order of 0.1 μF, it has been difficult to miniaturize a receiver in whole, and it has been impossible to integrate the receiver over one chip. In contrast, the optical receiver-amplifier according to the invention is suitable for miniaturization, and is adaptable for integration because the capacitor 63 having capacitance as small as on the order of 10 pF at the most is used therein. Furthermore, the optical receiver-amplifier can cope with faster operation since the capacitor mounted in the integrated circuit has a small capacitance value, and can cope with an optical transmission signal having a wideband frequency component if it is combined with the external capacitor.

Further, because the optical receiver-amplifier is provided with the DC current compensating circuit 6, the DC current component of a main signal is supplied to the DC current compensating circuit 6, and the DC current resulting from the feedback control can be delivered to the photodiode 1 connected to the input terminal of the transimpedance amp 2, whereupon the given output voltage level can be gained from the transimpedance amp 2 regardless of magnitude of light received by the photodiode 1.

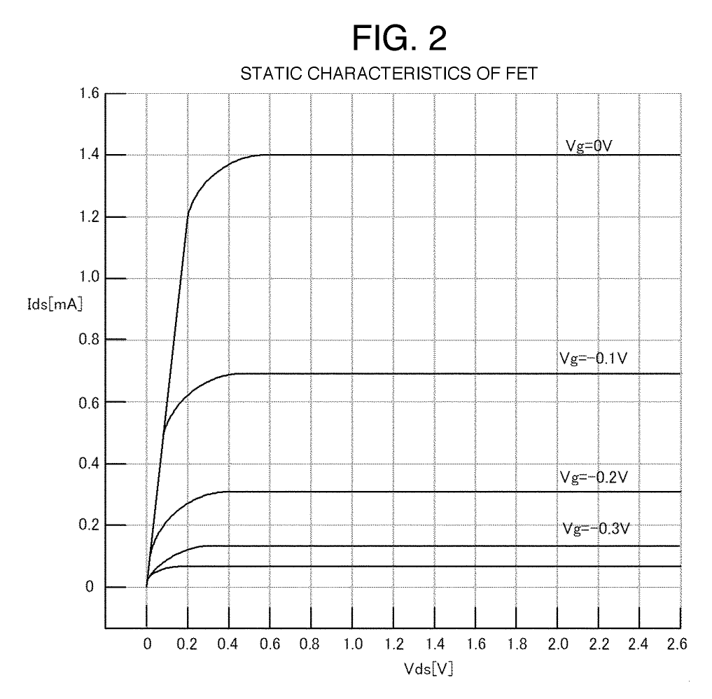

FIG. 2 is a view showing an example of static characteristics of an FET for use as the current source 64. This is a graph prepared by plotting static characteristics of source-to-drain current Ids against source-to-drain voltage Vds in the case of varying a gate control voltage Vg. Since respective flat parts of the graph represent a saturation region where ΔVds/ΔIds is large, and a dynamic resistance between the source and the drain is very high, the saturation region is used as a constant current source in the DC current compensating circuit 6.

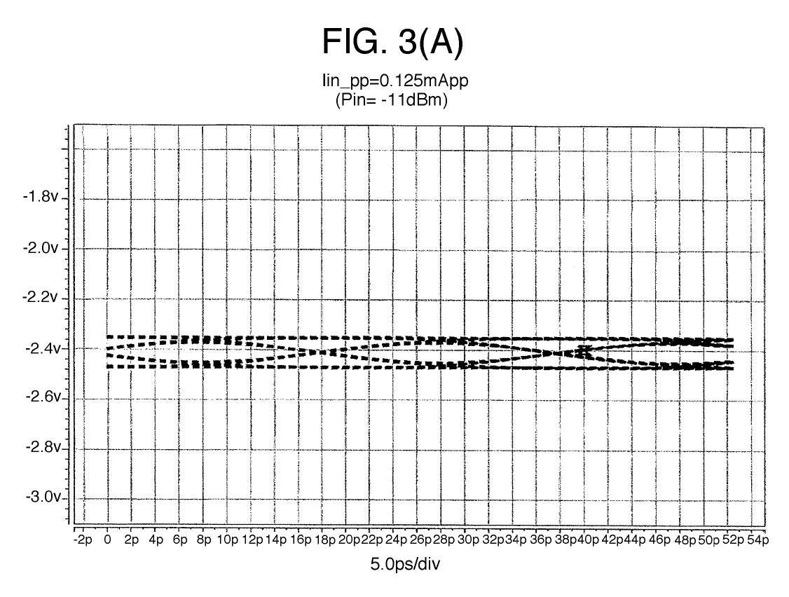

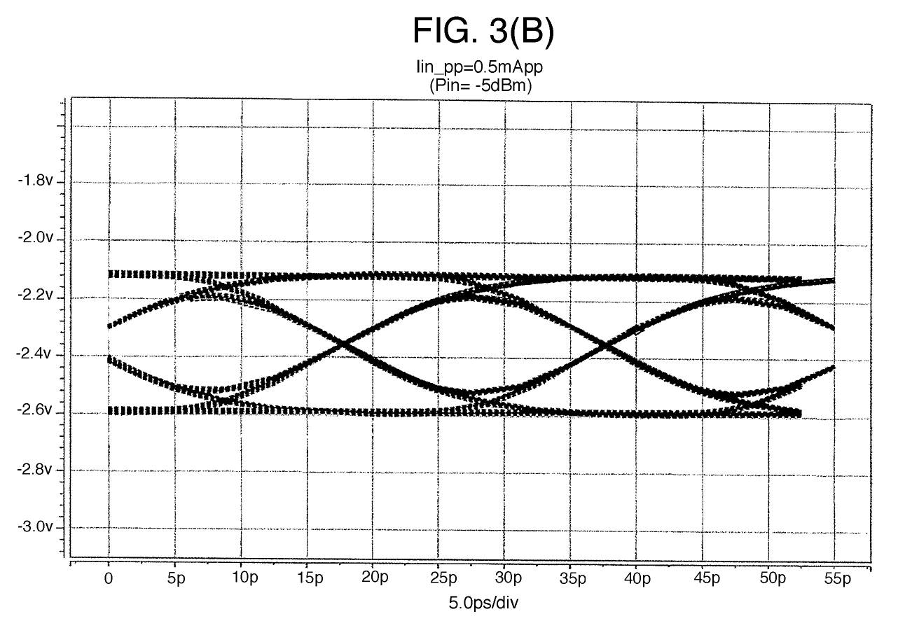

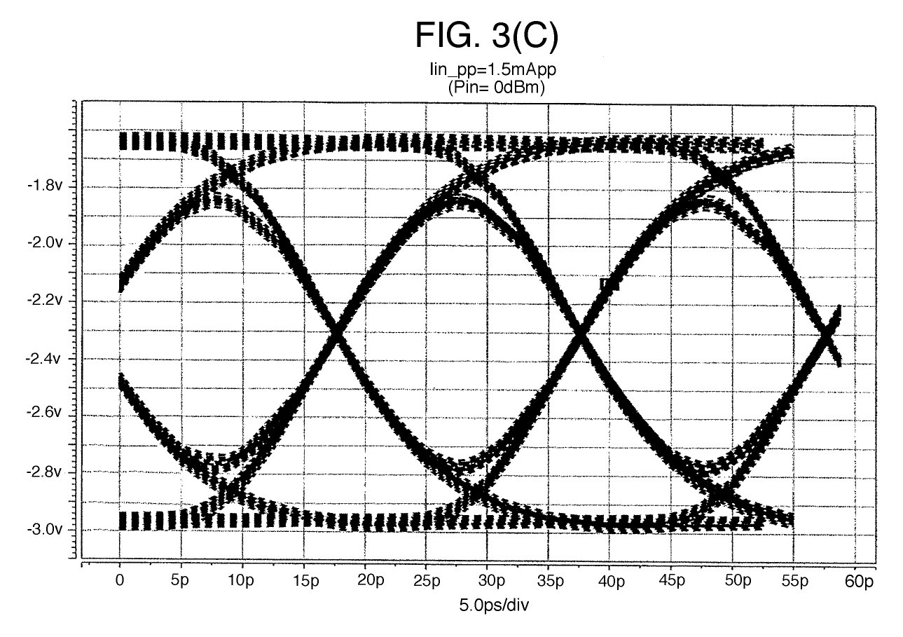

FIGS. 3(A), (B) and 3(C) are views showing results of a simulation of the output of the transimpedance amp 2 by way of example. It can be confirmed that the output is amplified to the same extent in directions more plus, and more minus from −2.4V, respectively, centering round the reference voltage −2.4V, and a DC level at the center of the output waveform undergoes amplification in such a state as to maintain the given output voltage level. It can be confirmed from FIGS. 3(A), 3(B) that if current resulting from electrical conversion of optical input power Pin is increased by four times, voltage amplitude will be greater by about four times while it can be confirmed from FIGS. 3(B), 3(C) that if the current resulting from electrical conversion of the optical input power Pin is increased by three times, voltage amplitude will be greater by about three times. In other words, voltage is amplified by times equivalent to times by which a current amount is increased.

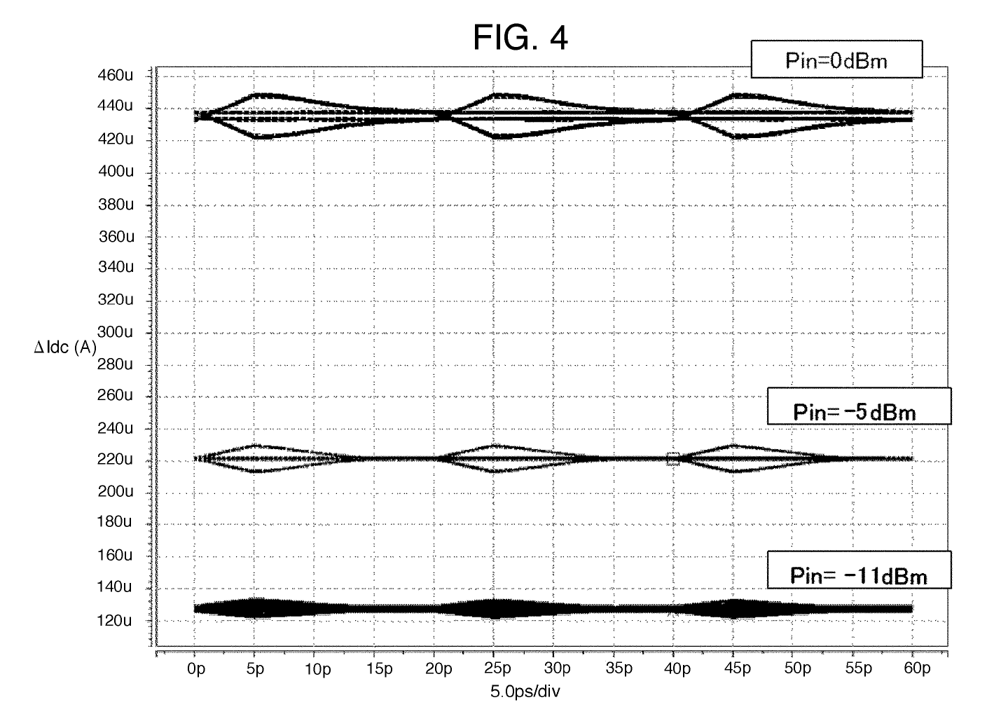

Further, FIG. 4 is view showing results of a simulation of current compensation due to feedback control against optical input power Pin received by the photodiode 1 by way of example. FIG. 4 shows DC current values (Iin) compensated by the DC current compensating circuit 6 against a given optical input power Pin (=0 dBm, −5 dBm, and −11 dBm), as is the case with FIGS. 3(A), 3(B) and 3(C). That is, it is found in the figure that the DC currents of the photodiode, corresponding to respective optical input powers Pin (=0 dBm, −5 dBm, and −11 dBm), are compensated for.

The differential limiter amp section 7 is capable of controlling the duty ratio (the cross-point) of the output signal to 50% by adjusting a potential difference.

Further, the output cross-point compensating circuit 73, that is, feedback control means are added to a differential amplification part of the limiter amp 71 of the differential limiter amp section 7, thereby enabling differential outputs of the differential amplification part of the limiter amp 71 to be automatically controlled with high precision.

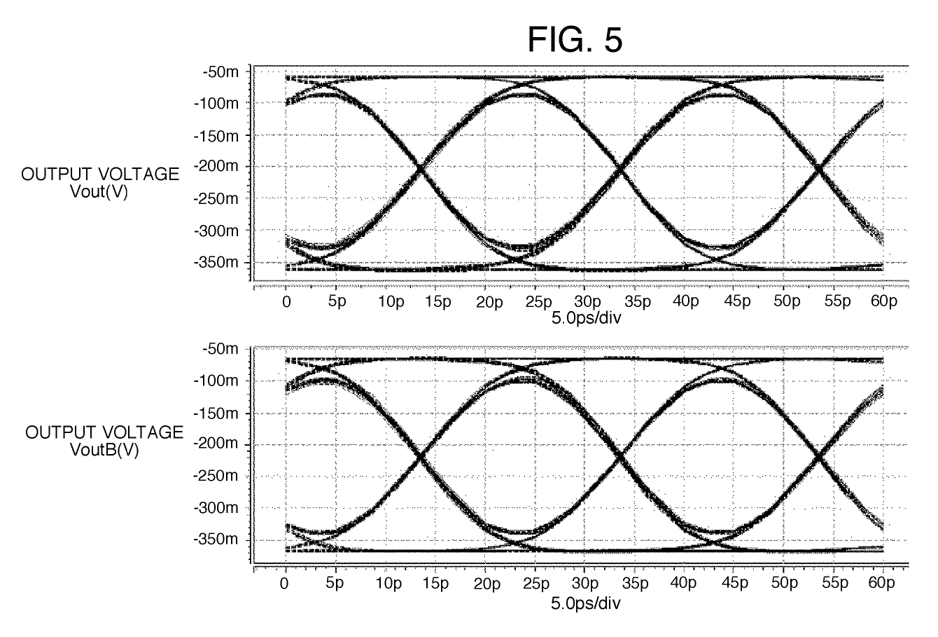

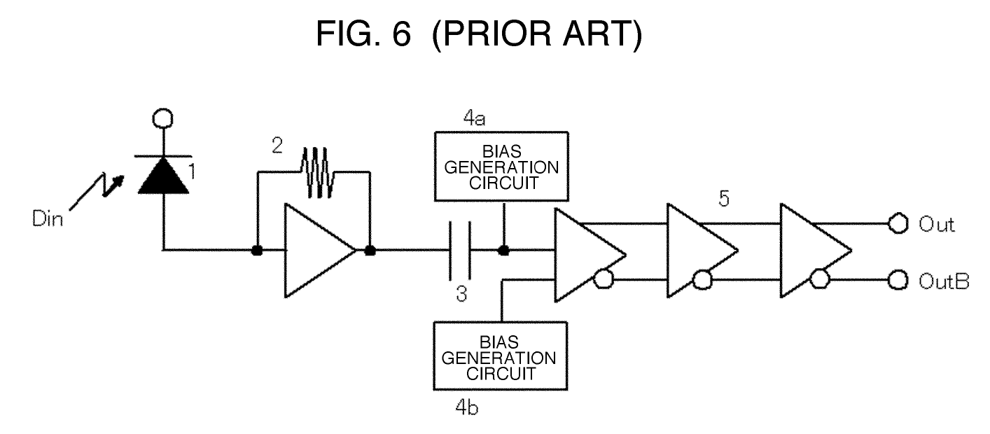

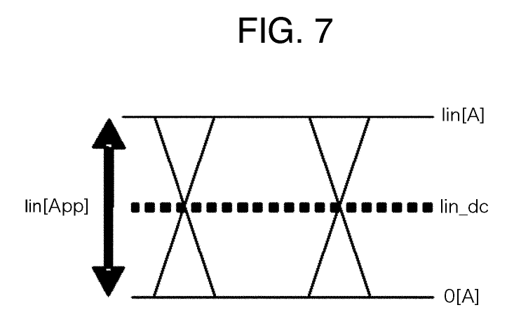

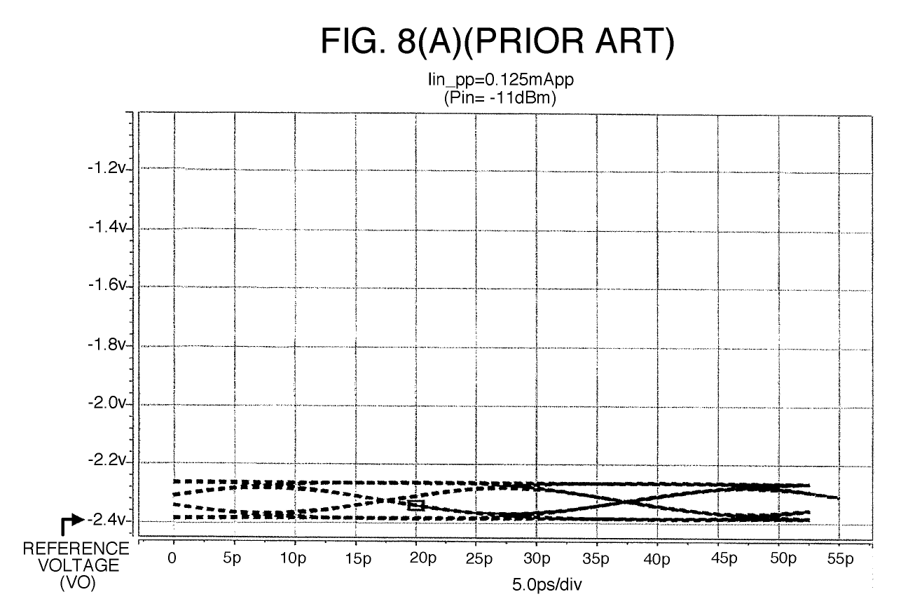

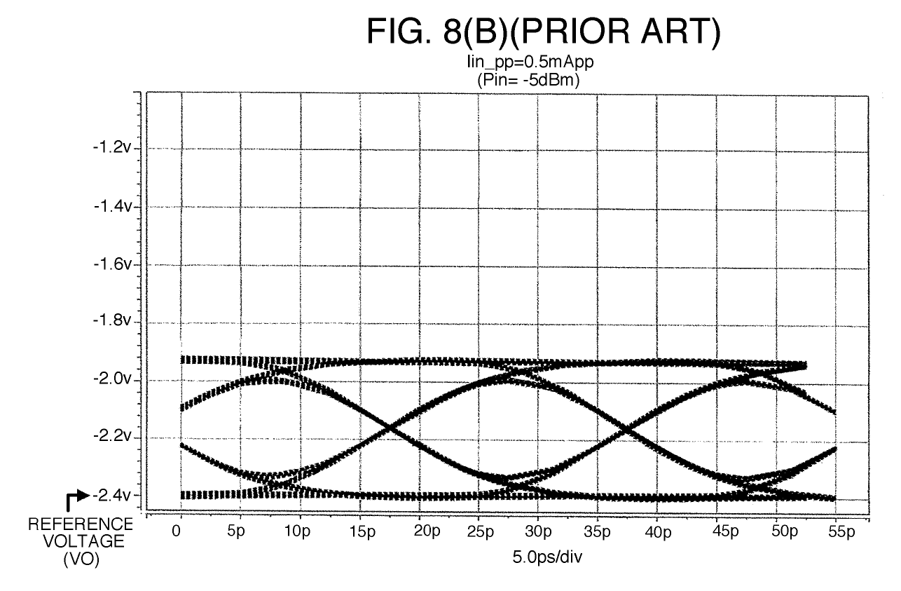

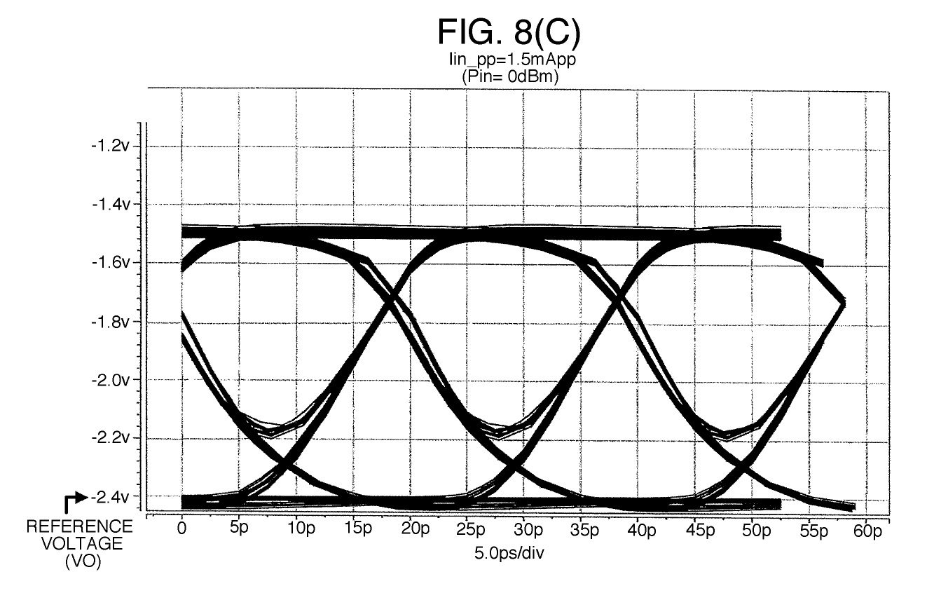

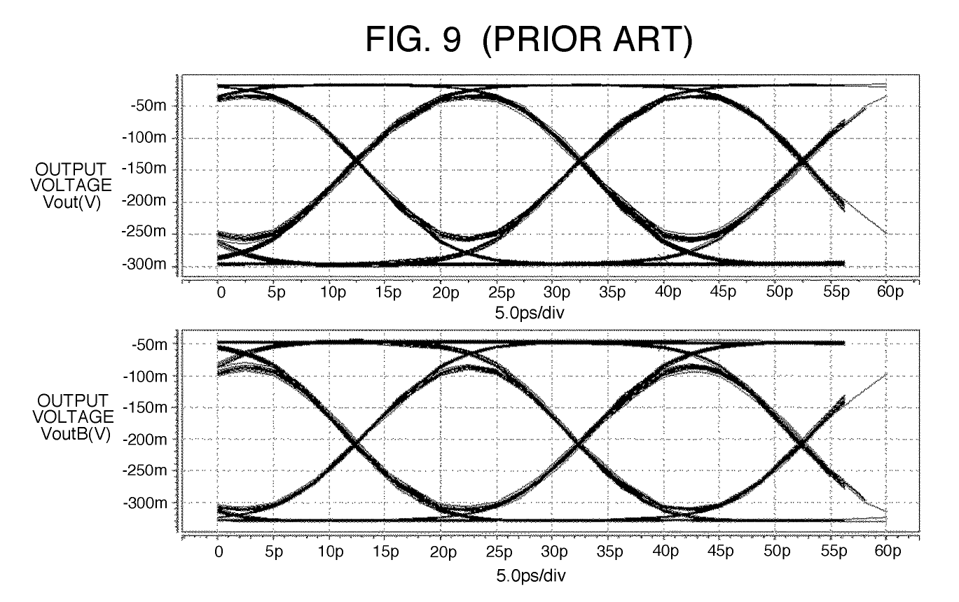

FIG. 5 is a view showing simulation output waveforms by use of feedback control against an output cross point by way of example. It can be confirmed that with the present invention using feedback control, the differential outputs of the limiter amp 71, as shown in the form of a simulation waveform, are symmetrically displayed with high precision as compared with the conventional case.

Further, the present invention is applicable not only to an integrated circuit employing the FET (field effect transistor) but also to an integrated circuit employing the bipolar transistor (junction-type transistor).

As described in the foregoing, with the present invention, it is possible to implement an optical receiver-amplifier having excellent characteristics in that the need for a large capacitance capacitor for AC coupling is eliminated to thereby enable miniaturization of a receiver in whole, and output waveforms of the differential limiter amp can be rendered symmetrical with high precision while the transimpedance amp and the limiter amp can be integrated over one chip.

1. An optical receiver-amplifier comprising:
a photodiode;
a transimpedance amp for amplifying an output signal of the photodiode; and
a DC current compensating circuit connected in parallel with the transimpedance amp for compensating for a DC-current component of an output current of the differential amp.

2. The optical receiver-amplifier according to claim 1, wherein the DC current compensating circuit comprises:
a differential amp, an output signal of the transimpedance amp being inputted to one of input terminals of the differential amp;
a bias generation circuit for inputting a set voltage to the other input terminal of the differential amp;
a capacitor coupled between an output terminal of the differential amp and an earth ground; and
a current source for receiving an output signal of the differential amp and compensating for a DC current flowing through the photodiode.

3. The optical receiver-amplifier according to claim 1, wherein the optical receiver-amplifier further comprises a differential limiter amp section connected to an output terminal of the transimpedance amp, comprising an output cross-point compensating circuit for adjusting a duty ratio of the output signal of the transimpedance amp by adjusting a potential difference.

4. The optical receiver-amplifier according to claim 1, wherein the optical receiver-amplifier is made up as an integrated circuit over one chip.

5. The optical receiver-amplifier according to claim 4, wherein the integrated circuit is composed of current control type bipolar transistors.
